(19) United States
(12) Patent Application Publication
(10) Pub. No.: US 2025/0385093 A1
(43) Pub. Date: Dec. 18, 2025

(54) UNDERLAYER WITH FLUORINE FOR EXTREME ULTRAVIOLET (EUV) LITHOGRAPHY

(71) Applicant: Applied Materials, Inc., Santa Clara, CA (US)

(72) Inventors: NANCY FUNG, Livermore, CA (US); LARRY GAO, Fremont, CA (US); LIKUN WANG, Cupertino, CA (US); HIDEYUKI KANZAWA, Halfmoon, NY (US); LEQUN LIU, San Jose, CA (US)

(21) Appl. No.: 19/215,203

(22) Filed: May 21, 2025

Related U.S. Application Data
(60) Provisional application No. 63/660,972, filed on Jun. 17, 2024.

(51) Int. Cl. H01L 21/033; G03F 7/20

(52) U.S. Cl. CPC H01L 21/0337; G03F 7/2004; H01L 21/0332

(57) ABSTRACT

Embodiments described herein relate to a method that includes forming an underlayer over a substrate, wherein the underlayer is an extreme ultraviolet (EUV) resist that includes carbon and fluorine. In an embodiment, the method includes forming a resist layer over the underlayer, wherein the resist layer is an EUV chemically amplified resist (CAR). In an embodiment, the method includes exposing the resist layer and the underlayer to EUV electromagnetic radiation, wherein fluorine from the underlayer diffuses into the resist layer. In an embodiment, the method includes developing the resist layer.

### CROSS-REFERENCE TO RELATED APPLICATIONS

This application claims the benefit of U.S. Provisional Application No. 63/660,972, filed on Jun. 17, 2024, the entire contents of which are hereby incorporated by reference herein.

### BACKGROUND

### 1) Field

Embodiments relate to the field of semiconductor manufacturing and, in particular, extreme ultraviolet (EUV) patterning with an underlayer that is EUV activated and comprises fluorine.

### 2) Description of Related Art

Extreme ultraviolet (EUV) photoresist materials generally have low efficiency and require high dosages in order to obtain a desired contrast between exposed and unexposed regions. Further, a low EUV dose typically results in higher line edge roughness (LER), higher line width roughness (LWR), and poor local critical dimension uniformity (LCDU). Increasing the dose reduces throughput, which increases the overall cost of the lithography process.

Accordingly, attempts to increase EUV efficiency of photoresist materials are of particular interest to the industry. Different material systems, such as metal oxide resists (MORs), chemically amplified resists (CARs), and the like have been developed to improve contrast after exposure. Some approaches have also proposed the use of underlayer materials in order to improve the efficiency of the photoresist material. In some instances, the underlayer also reacts under a stimulus (e.g., heat, electromagnetic radiation, etc.) in order to drive additional species from the underlayer into the photoresist layer to improve chemical conversion of the photoresist layer.

### SUMMARY

Embodiments described herein relate to a method that includes forming an underlayer over a substrate, wherein the underlayer is an extreme ultraviolet (EUV) resist that includes carbon and fluorine. In an embodiment, the method includes forming a resist layer over the underlayer, wherein the resist layer is an EUV chemically amplified resist (CAR). In an embodiment, the method includes exposing the resist layer and the underlayer to EUV electromagnetic radiation, wherein fluorine from the underlayer diffuses into the resist layer. In an embodiment, the method includes developing the resist layer.

Embodiments described herein relate to a patterning stack that includes a substrate, and an underlayer over the substrate, wherein the underlayer includes carbon and fluorine, and wherein the underlayer is an extreme ultraviolet (EUV) resist. In an embodiment, the patterning stack includes a resist layer over the underlayer, wherein the resist layer is an EUV chemically amplified resist (CAR).

Embodiments described herein relate to a method that includes depositing an underlayer on a substrate with a dry deposition process, wherein the underlayer includes carbon and fluorine, and wherein the underlayer has a first region with a first fluorine concentration and a second region above the first region with a second fluorine concentration that is lower than the first fluorine concentration; treating a surface of the underlayer to increase a concentration of hydrogen at the surface of the underlayer. In an embodiment, the method includes forming a resist layer over the underlayer, wherein the resist layer is an EUV chemically amplified resist (CAR), and exposing the resist layer and the underlayer to EUV electromagnetic radiation, wherein fluorine from the underlayer diffuses into the resist layer. In an embodiment, the method includes developing the resist layer.

### BRIEF DESCRIPTION OF THE DRAWINGS

FIG. 1A is a cross-sectional illustration of a substrate with a patterning stack that includes an underlayer and a resist layer, in accordance with an embodiment.

FIG. 1B is a cross-sectional illustration of the patterning stack during an extreme ultraviolet (EUV) exposure of the patterning stack, in accordance with an embodiment.

FIG. 1C is a cross-sectional illustration of the patterning stack after the resist layer is developed with the presence of scum at the bottom of the pattern, in accordance with an embodiment.

FIG. 1D is a cross-sectional illustration of the patterning stack after the pattern in the resist layer is transferred into the underlayer, in accordance with an embodiment.

FIG. 2A is a cross-sectional illustration of a substrate with a patterning stack that includes an underlayer that comprises fluorine and a resist layer, in accordance with an embodiment.

FIG. 2B is a cross-sectional illustration of the patterning stack during an EUV exposure that drives local diffusion of fluorine from the underlayer into the resist layer, in accordance with an embodiment.

FIG. 2C is a cross-sectional illustration of the patterning stack after the resist layer is patterned, in accordance with an embodiment.

FIG. 2D is a cross-sectional illustration of the patterning stack after the pattern in the resist layer is transferred into the underlayer, in accordance with an embodiment.

FIG. 3A is a cross-sectional illustration of the patterning stack with an underlayer with a substantially uniform concentration of fluorine, in accordance with an embodiment.

FIG. 3B is a cross-sectional illustration of the patterning stack with an underlayer that comprises a region of low fluorine concentration at a surface of the underlayer, in accordance with an embodiment.

FIG. 3C is a cross-sectional illustration of the patterning stack with an underlayer that comprises a hydrogen treated surface, in accordance with an embodiment.

FIG. 3D is a cross-sectional illustration of the patterning stack with an underlayer that comprises alternating sub-layers with high and low fluorine concentrations, in accordance with an embodiment.

FIG. 4 is a flow diagram of a process for patterning a patterning stack with an underlayer that comprises fluorine, in accordance with an embodiment.

FIG. 5 is a flow diagram of a process for patterning a patterning stack with an underlayer that comprises fluorine and a hydrogen treated surface, in accordance with an embodiment.

FIG. 6 illustrates a block diagram of an exemplary computer system that may be used in conjunction with a processing tool, in accordance with an embodiment.

### DETAILED DESCRIPTION

Embodiments described herein include extreme ultraviolet (EUV) patterning with an EUV underlayer that comprises fluorine. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, EUV photoresist material systems are limited due to the need for high dosages in order to obtain the desired contrast with suitable line edge roughness (LER), line width roughness (LWR), and local critical dimension uniformity (LCDU). Lower dosages also may result in the presence of scum along the bottom surface of the pattern in the resist layer. That is, residual resist material may be provided along the top surface of the underlayer at the bottom of the pattern.

In the case of a chemically amplified resist (CAR), the scum is the result of an incomplete clearing of the exposed resist material. This can occur when the resist material is not sufficiently deprotected through a photoactivated acid-anion catalyst that changes the solubility of the resist. As such, the entire exposed region of the CAR resist is not able to be removed during the developing process. The presence of scum along the bottom of the pattern is problematic. For example, patterns that are not fully cleared can lead to electrical bridging in the device and/or missing contact defects. Both of which can negatively impact device yield.

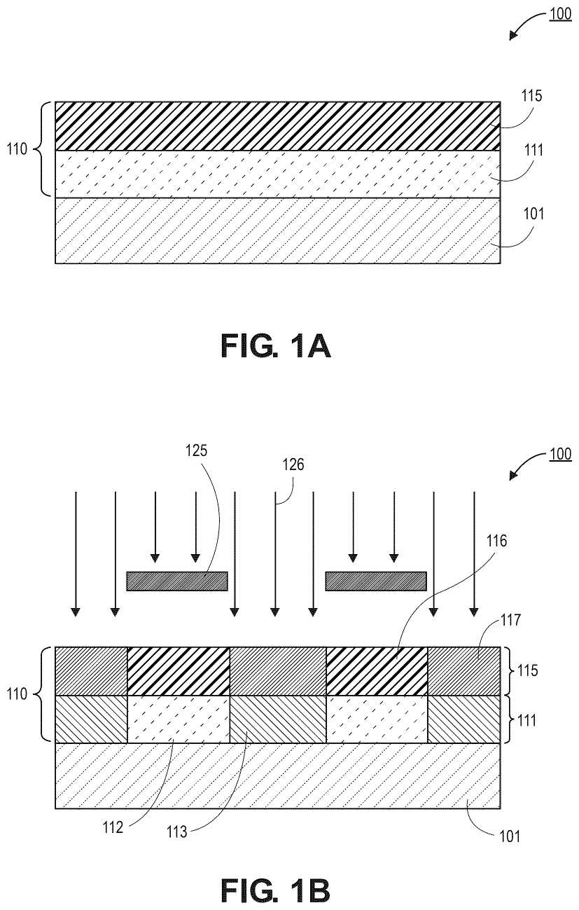

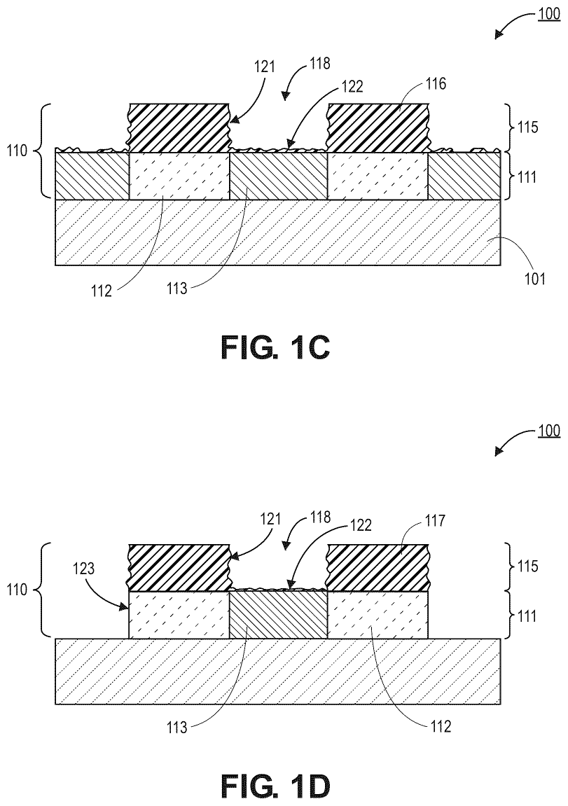

Referring now to FIGS. 1A-1D, a series of cross-sectional illustrations depicting an example of such an underlayer system with incomplete development of the resist layer is shown, in accordance with an embodiment.

Referring now to FIG. 1A, a cross-sectional illustration of a device 100 is shown, in accordance with an embodiment. In an embodiment, the device 100 comprises a substrate 101. The substrate 101 may be a semiconductor substrate, such as a silicon wafer or the like. Though, any material (e.g., glass, ceramic, etc.) may be used for the substrate 101 in other embodiments. In an embodiment, a patterning stack 110 is provided over the substrate 101. In the illustration of FIG. 1A, the patterning stack 110 comprises an underlayer 111 and a photoresist layer 115 over the underlayer 111. Though, it is to be appreciated that the patterning stack 110 may include one or more additional layers, such as oxide layers, carbon layers, antireflective coating (ARC) layers, silicon layers, and/or the like. In some instances, the one or more additional layers may be provided between the underlayer 111 and the substrate 101.

In an embodiment, the photoresist layer 115 may be an EUV sensitive material. That is, exposure of the photoresist layer 115 to EUV electromagnetic radiation may result in a chemical reaction in the exposed regions. For example, a deprotection reaction may be initiated by the EUV exposure when the photoresist layer 115 is a CAR. In some instances, the photoresist layer 115 may also be referred to as a resist layer 115 for simplicity. In an embodiment, the underlayer 111 may be a polymer material that is sensitive to EUV electromagnetic radiation.

Referring now to FIG. 1B, a cross-sectional illustration of the device 100 during an EUV exposure process is shown, in accordance with an embodiment. In an embodiment, the EUV exposure process may include selectively exposing the patterning stack 110 to EUV electromagnetic radiation 126. The EUV electromagnetic radiation 126 may be blocked at certain locations by a mask 125, reticle, or the like. The portion of the EUV electromagnetic radiation 126 that reaches the patterning stack 110 results in the formation of exposed resist regions 117 and unexposed resist regions 116 in the resist layer 115. The underlayer 111 may also have exposed regions 113 and unexposed regions 112.

Referring now to FIG. 1C, a cross-sectional illustration of the device 100 after the resist layer 115 is developed is shown, in accordance with an embodiment. The developing process may result in the removal of the exposed resist regions 117. However, due to the insufficient amounts of deprotection in the exposed resist regions 117, the developing process may not result in a pattern 118 that meets the desired specifications. For example, sidewalls 121 of the pattern 118 may have a high roughness that leads to poor LER, LWR, and/or LCDU. Further, the developing process may not fully clear the exposed resist regions 117 from the pattern 118. This can lead to the presence of scum 122 at the bottom of the pattern 118. The high roughness of the sidewalls 121 and the scum 122 may result in suboptimal pattern transfer into underlying layers.

Referring now to FIG. 1D, a cross-sectional illustration of the device 100 after the pattern 118 in the resist layer 115 is transferred into the underlayer 111 with an etching process is shown, in accordance with an embodiment. As shown, the underlayer 111 will also have sidewalls 123 that have a high roughness due to the high roughness of the sidewalls 121 in the resist layer 115. Further, the presence of the scum 122 may result in incomplete pattern transfer in the underlayer 111. For example, the central exposed region 113 is not removed at all due to a thick layer of scum 122. Such patterning defects can lead to electrical bridging or missing contact defects in the device 100.

Accordingly, embodiments disclosed herein comprise an optimized underlayer material system. Particularly, the underlayers described herein include material compositions that are tuned to selectively release fluorine into the exposed regions of the overlying resist layer. That is, the fluorine that diffuses into the resist layer originates primarily from the exposed regions of the underlayer. As such, the unexposed regions of the resist layer are not provided significant amounts of fluorine. This preserves the unexposed regions resistance to the deprotection reaction and can improve the etch selectivity between the exposed region of the resist layer and the unexposed region of the resist layer.

In an embodiment, the presence of fluorine in the exposed regions of the overlying resist layer enhances the deprotection reaction of the exposed regions of the resist layer. Since the deprotection reaction is improved, the total dose of EUV electromagnetic radiation can be decreased while still allowing for the complete clearance of the exposed regions during the development process. This allows for improved throughput and reduces cost of the lithography process.

In an embodiment, the underlayer may be formed with any suitable deposition process. For example, the underlayer may be deposited with an atomic layer deposition (ALD) process, a chemical vapor deposition (CVD) process, a molecular layer deposition (MLD) process, or a spin-on process. In an embodiment, the fluorine may be integrated into the underlayer with any suitable process, such as an in-situ doping process, a plasma doping (PLAD) process, a beamline implant process, an ion implantation process, or gas phase doping.

The flexibility between the type of deposition process used and/or the fluorine implantation process may allow for the concentration of the underlayer to be variable through a thickness of the underlayer. In a particular embodiment, the underlayer may have a first fluorine concentration in a bulk of the underlayer and a second fluorine concentration proximate to a surface of the underlayer that interfaces with resist layer. For example, the second fluorine concentration may be lower than the first fluorine concentration. A lower second fluorine concentration (which may comprise substantially no fluorine) may be beneficial to improve adhesion between the underlayer and the resist layer. Spacing the bulk of the fluorine away from the interface is not problematic since the fluorine will readily diffuse through the underlayer towards the resist layer. In some embodiments, a treatment for incorporating excess hydrogen into the surface of the underlayer (e.g., to provide extra CH₄ at the interface) may also be used to improve adhesion between the underlayer and the resist layer.

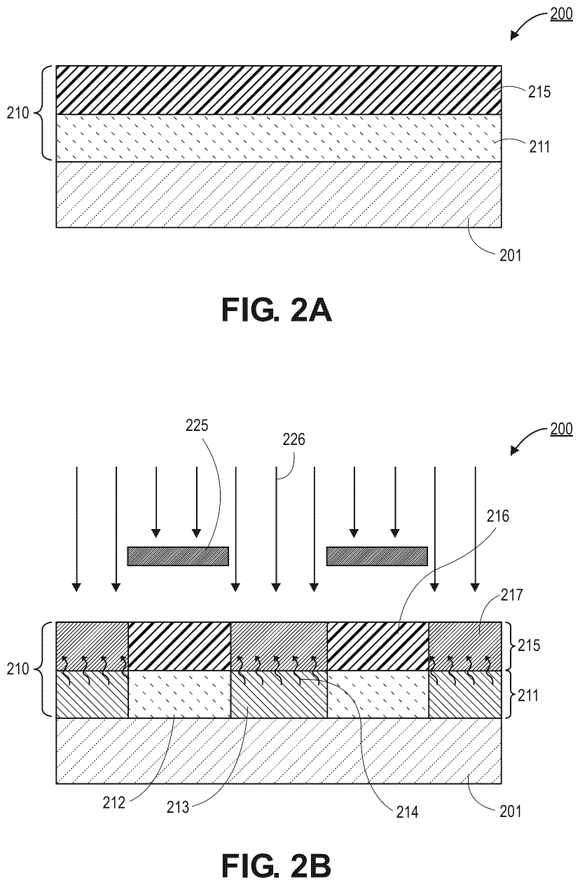

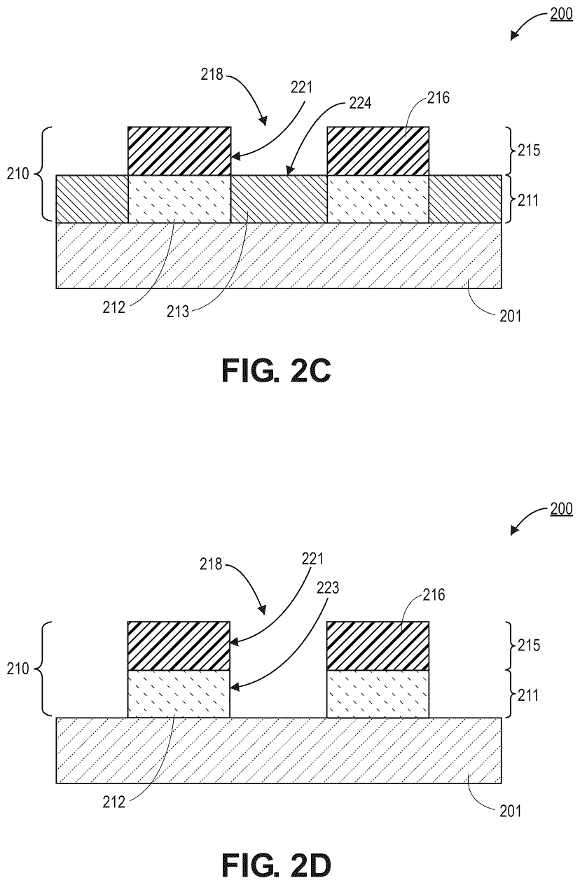

Referring now to FIGS. 2A-2D, a series of cross-sectional illustrations depicting a process for patterning a patterning stack with an underlayer and a resist layer over the underlayer is shown, in accordance with an embodiment. In an embodiment, the underlayer of the patterning stack may be doped with fluorine for implementing selective diffusion of fluorine into the exposed regions of the resist layer.

Referring now to FIG. 2A, a cross-sectional illustration of a device 200 is shown, in accordance with an embodiment. In an embodiment, the device 200 comprises a substrate 201. The substrate 201 may be a semiconductor substrate, such as a silicon wafer or the like. Though, any material (e.g., glass, ceramic, etc.) may be used for the substrate 201 in other embodiments. In an embodiment, a patterning stack 210 is provided over the substrate 201. In the illustration of FIG. 2A, the patterning stack 210 comprises an underlayer 211 and a photoresist layer 215 over the underlayer 211. Though, it is to be appreciated that the patterning stack 210 may include one or more additional layers, such as oxide layers, carbon layers, ARC layers, silicon layers, and/or the like. In some instances, the one or more additional layers may be provided between the underlayer 211 and the substrate 201.

In an embodiment, the photoresist layer 215 may be an EUV sensitive material. That is, exposure of the photoresist layer 215 to EUV electromagnetic radiation may result in a chemical reaction in the exposed regions. The photoresist layer 215 may include any suitable EUV photoresist material. In a particular embodiment, the photoresist layer 215 is a CAR. In some instances, the photoresist layer 215 may also be referred to as a resist layer 215 for simplicity.

In an embodiment, the underlayer 211 may also comprises an EUV sensitive material that comprises carbon and fluorine. The fluorine may be bonded to carbon to form C—F species in some embodiments. Portions of the underlayer 211 that are exposed to EUV electromagnetic radiation may undergo a chemical reaction that includes a deprotection reaction. In some instances, the chemical reaction driven by the EUV exposure may result in the release and/or diffusion of fluorine within the underlayer 211.

In an embodiment, one or both of the underlayer 211 and the resist layer 215 may be deposited with a chemical vapor deposition (CVD) process. In the case where both the underlayer 211 and the resist layer 215 are deposited with a CVD process, a single deposition chamber may be used in order to form the underlayer 211 and the resist layer 215 over the substrate 201. Further, the use of a dry deposition process, such as CVD, allows for concentration variations through a thickness of the underlayer 211 and/or the resist layer 215. For example, a lower region of the underlayer 211 may have a high fluorine concentration, while and upper region of the underlayer 211 may have a lower fluorine concentration to improve adhesion between the resist layer 215 and the underlayer 211. Though, any of the fluorine concentration profiles described in greater detail herein may be used for the underlayer 211.

Referring now to FIG. 2B, a cross-sectional illustration of the device 200 during an EUV exposure process is shown, in accordance with an embodiment. In an embodiment, the EUV exposure process may include selectively exposing the patterning stack 210 to EUV electromagnetic radiation 226. The EUV electromagnetic radiation 226 may be blocked at certain locations by a mask 225, reticle, or the like. The portion of the EUV electromagnetic radiation 226 that reaches the patterning stack 210 results in the formation of exposed resist regions 217 and unexposed resist regions 216 in the resist layer 215. The underlayer 211 may also have exposed regions 213 and unexposed regions 212. For example, the exposed regions 213 may be deprotected or the like. In an embodiment, the EUV exposure of the exposed resist regions 217 may also initiate a deprotection reaction in the exposed resist regions 217.

In an embodiment, the EUV exposure of the exposed regions 213 of the underlayer 211 may result in the release and/or diffusion of fluorine 214 into the exposed resist regions 217. Particularly, it is to be appreciated that substantially all fluorine 214 that diffuses into the exposed resist regions 217 may originate from the exposed regions 213 of the underlayer 211. That is, even though the unexposed regions 212 of the underlayer 211 comprise fluorine 214, the fluorine 214 in the unexposed regions 213 is not mobile through diffusion. Accordingly, only the exposed resist regions 217 receive significant amounts of fluorine 214 from the underlayer 211.

In some embodiments, diffusion of the fluorine 214 into the resist layer 215 may be improved through by elevating a temperature of the device 200 during the EUV exposure and/or after the EUV exposure. For example, the temperature of the underlayer 211 may be raised to approximately 150° C. or higher in some embodiments.

Referring now to FIG. 2C, a cross-sectional illustration of the device 200 after the resist layer 215 is developed is shown, in accordance with an embodiment. The developing process may result in the removal of the exposed resist regions 217. That is, the deprotection reaction may allow for the exposed resist regions 217 to be easily dissolved or etched while leaving behind the unexposed resist regions 216. Due to the improved contrast performance of the resist layer 215 resulting from the selective release of the fluorine 214, the sidewalls 221 of the pattern 218 have a lower surface roughness than previous patterning stack systems.

Additionally, the presence of scum at the bottom of the pattern 218 is reduced or completely eliminated. This can be due, at least in part, to a high concentration of fluorine 214 at the lower surface of the exposed resist regions 217. As such, a top surface 224 of the unexposed regions 212 of the underlayer 211 is substantially exposed. Accordingly, such a patterning stack 210 allows for overall reductions in the EUV dose while still maintaining low LER, low LWR, and/or high LCDU. In an embodiment, the development of the resist layer 215 may be implemented with a dry develop process (e.g., a thermal etch, a plasma etch, etc.). In such an embodiment, the dry develop process may be implemented within the same cluster tool that comprises the deposition chamber used to deposit the patterning stack 210.

Referring now to FIG. 2D, a cross-sectional illustration of the device 200 after the pattern 218 in the resist layer 215 is transferred into the underlayer 211 with an etching process is shown, in accordance with an embodiment. As shown, the underlayer 211 will also have sidewalls 223 that have a low roughness due to the low roughness of the sidewalls 221 in the resist layer 215. Since there is little (or no) scum, the pattern 218 transfer process is more efficient, and patterning defects (e.g., electrical bridging, missing contact defects, etc.) are prevented. Accordingly, as CDs continue to shrink in advanced semiconductor devices, enhanced LER, LWR, and/or LCDU will significantly improve overall device 200 performance. In an embodiment, the pattern 218 transfer process may be implemented with a dry etching process (e.g., a thermal etch, a plasma etch, etc.). In such an embodiment, the dry etching process may be implemented within the same tool used for the resist layer 215 development. Further, the dry etching for pattern 218 transfer into the underlayer 211 may be implemented in the cluster tool that incorporates the deposition chamber used to deposit the patterning stack 210.

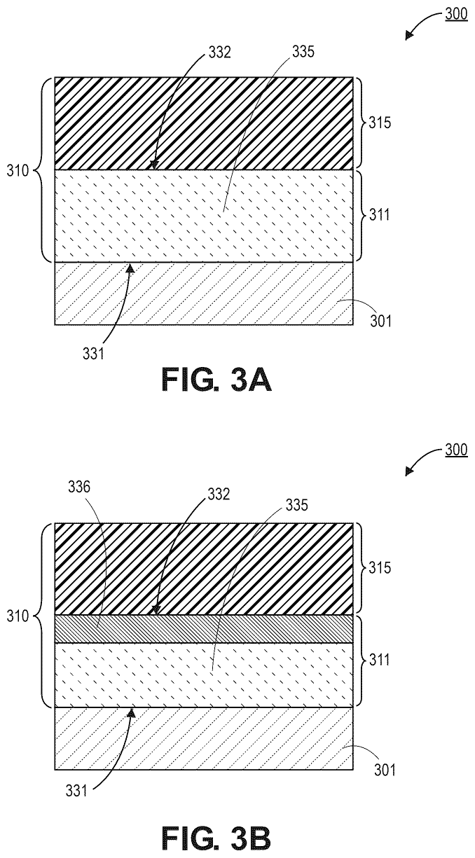

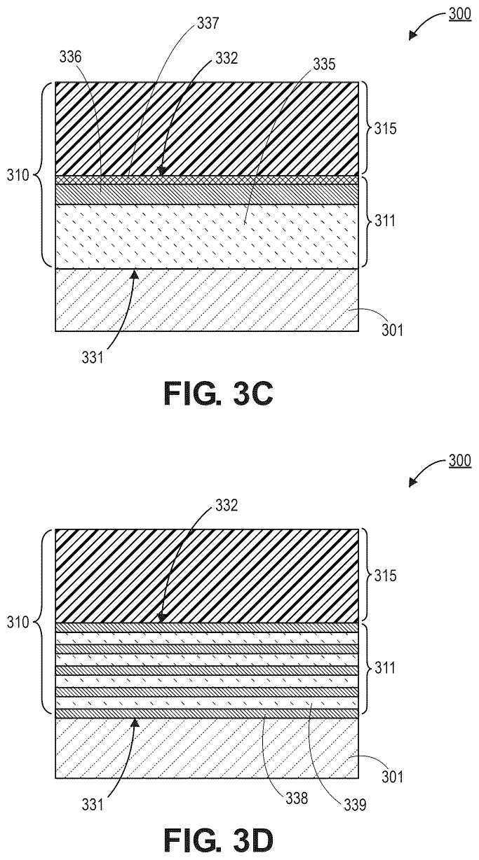

Referring now to FIGS. 3A-3D, a series of cross-sectional illustrations of devices 300 with various patterning stacks 310 over a substrate 301 is shown, in accordance with an embodiment. In each of the devices 300, the patterning stacks 310 may comprise an underlayer 311 over the substrate 301 and a resist layer 315 over the underlayer 311. In an embodiment, the resist layer 315 comprises an EUV CAR material, and the underlayer comprises an EUV sensitive material that comprises fluorine. Each of the devices 300 in FIGS. 3A-3D comprise different fluorine concentration profiles that may be enabled through the use of various deposition and/or doping processes.

Referring now to FIG. 3A, a cross-sectional illustration of a device 300 with a patterning stack 310 that includes an underlayer 311 with a uniform fluorine concentration through a thickness of the underlayer 311 is shown, in accordance with an embodiment. For example, a concentration of fluorine within a bulk 335 of the underlayer 311 is substantially uniform from a bottom surface 331 of the underlayer 311 to a top surface 332 of the underlayer 311.

Such an embodiment may be formed through the use of a dry deposition process that comprises depositing a fluorine doped carbon film through the use of a carbon containing precursor and a fluorine containing precursor in an ALD process, a CVD process, an MLD process, or the like. For example, the carbon containing precursor may comprise CO, CH₄ or the like, and the fluorine containing precursor may comprise CF₄. The two precursors may be flown into a chamber over the substrate at the same time or sequentially. For example, alternating pulses of the carbon containing precursor and the fluorine containing precursor may be flown into the chamber for any number of cycles. In other embodiments, a single precursor gas comprising carbon and fluorine (e.g., CHF₃) may be flown into the chamber. Integrating fluorine into the underlayer 311 with such a process may sometimes be referred to as an in-situ doping process.

Other embodiments may include treating carbon contain layers with a PLAD process that comprises fluorine, or through gas phase doping with a gas that comprises fluorine. Ion implantation, beamline implantation, or the like may also be used to uniformly implant fluorine into the underlayer 311 in other embodiments. Uniform fluorine concentrations in the bulk 335 may also be provided with a spin-on process.

Referring now to FIG. 3B, a cross-sectional illustration of a device 300 with an underlayer 311 that comprises a non-uniform fluorine concentration through a thickness of the underlayer 311 is shown, in accordance with an embodiment. In an embodiment, the underlayer 311 may comprise a bulk 335 with a first fluorine concentration and an upper region 336 proximate to the top surface 332 of the underlayer 311 that has a second fluorine concentration. In an embodiment, the second fluorine concentration is lower than the first fluorine concentration. In some embodiments, the second fluorine concentration may be substantially free of fluorine. That is, the upper region 336 may have approximately 1% by weight of fluorine or less.

Such an embodiment with a low fluorine concentration in the upper region 336 may be beneficial for improving adhesion between the resist layer 315 and the underlayer 311. This is because bonds from the resist layer 315 to the fluorine are weaker than bonds from the resist layer 315 to hydrogen and/or carbon. Additionally, the fluorine has good mobility and can easily diffuse through the upper region 336 when released by the EUV exposure. As such, spacing the fluorine away from the interface does not negatively impact the deprotection reaction improvement provided by the underlayer 311.

In an embodiment, the non-uniform concentration may be made through the combination of any of the deposition and/or doping processes described in greater detail herein. For example, the bulk 335 may be doped with fluorine with any of the doping processes and the upper region 336 may be doped with fluorine at a lower concentration and/or remain substantially free from fluorine dopants.

Referring now to FIG. 3C, a cross-sectional illustration of a device 300 with an underlayer 311 that comprises a non-uniform fluorine concentration through a thickness of the underlayer 311 and a treated surface 337 is shown, in accordance with an embodiment. In an embodiment, the underlayer 311 may comprise a bulk 335 with a first fluorine concentration and an upper region 336 proximate to the top surface 332 of the underlayer 311 that has a second fluorine concentration. In an embodiment, the second fluorine concentration is lower than the first fluorine concentration. The bulk 335 and the upper region 336 may be similar to the bulk 335 and upper region 336 described above with respect to FIG. 3B.

In an embodiment, the treated surface 337 may comprise a higher concentration of hydrogen than the rest of the underlayer 311. For example, a hydrogen surface treatment may be applied to the top surface 332 of the underlayer 311. The hydrogen surface treatment may include exposure to a plasma comprising hydrogen, hydrogen doping, gas phase doping with a hydrogen containing gas, and/or the like. Increasing the hydrogen concentration at the treated surface 337 may increase a number of CH species that are available for bonding with the resist layer 315. Accordingly, the adhesion between the resist layer 315 and the underlayer 311 can be improved. While a treated surface 337 is shown in combination with an underlayer with an otherwise non-uniform fluorine concentration, it is to be appreciated that a hydrogen treated surface 337 may also be used in conjunction with an underlayer 311 with a substantially uniform fluorine concentration through a thickness of the underlayer 311. For example, a treated surface 337 may be added to an embodiment similar to the device 300 described above with respect to FIG. 3A.

Referring now to FIG. 3D, a cross-sectional illustration of a device 300 with an underlayer 311 with a non-uniform fluorine concentration that comprises alternating first sub-layers 338 and second sub-layers 339 is shown, in accordance with an embodiment. In an embodiment, the first sub-layers 338 may have a first fluorine concentration and the second sub-layers 339 may have a second fluorine concentration that is different than the first fluorine concentration. For example, the first sub-layers 339 may be un-doped, and the second sub-layers 339 may be doped with fluorine. The doping and/or deposition processes used to form the alternating first sub-layers and the second sub-layers may be similar to any of those described in greater detail herein.

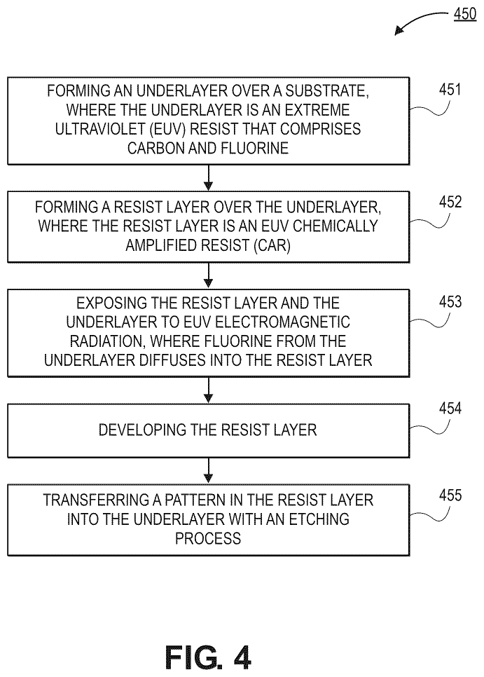

Referring now to FIG. 4, a flow diagram of a process 450 for patterning a patterning stack over a substrate with an underlayer that comprises fluorine is shown, in accordance with an embodiment. In an embodiment, the process may start with operation 451, which comprises forming an underlayer over a substrate. In an embodiment, the underlayer is an EUV resist that comprises carbon and fluorine. In some embodiments, the underlayer is formed with a dry deposition process that comprises a carbon containing precursor and a fluorine containing precursor. In an embodiment, the carbon containing precursor and the fluorine containing precursor are flown into a chamber simultaneously, or the carbon containing precursor and the fluorine containing precursor are flown into a chamber sequentially in one or more cycles. In some embodiments, the underlayer is formed with an ALD process, a CVD process, an MLD process, or a spin-on process. In an embodiment, the fluorine is integrated into the underlayer with an in-situ doping process, a PLAD process, a beamline implant process, an ion implantation process, or gas phase doping. In some embodiments, the underlayer may also be treated with a treatment that increases a concentration of hydrogen at the surface of the underlayer. Such an embodiment may improve adhesion between the resist layer and the underlayer.

In other embodiments, a concentration of fluorine is non-uniform through a thickness of the underlayer. For example, a first region of the underlayer may have a first concentration of fluorine and a second region of the underlayer that comprises a surface of the underlayer may have a second concentration of fluorine that is lower than the first concentration of fluorine. In some embodiments, the fluorine concentration in the second region is less than approximately 1% by weight.

In an embodiment, the process 450 may continue with operation 452, which comprises forming a resist layer over the underlayer. In an embodiment, the resist layer is an EUV CAR material. The resist layer may be deposited with a dry deposition process, a spin-coating process, or the like.

In an embodiment, the process 450 may continue with operation 453, which comprises exposing the resist layer and the underlayer to EUV electromagnetic radiation. In an embodiment, fluorine from the underlayer diffuses into the resist layer during and/or after the EUV exposure. In some embodiments, the underlayer may be heated in order to improve diffusion into the resist layer. In an embodiment, the diffusion of fluorine into the resist layer improves a deprotection reaction in the resist layer. Since the diffusion is activated by the EUV exposure, the fluorine diffuses into the resist layer from only regions of the underlayer that are exposed by the EUV electromagnetic radiation. As such the dose of EUV electromagnetic radiation can be reduced in order to improve throughput with minimal scum formation.

In an embodiment, the process 450 may continue with operation 454, which comprises developing the resist layer. The resist layer may be developed with a dissolving process, an etching process, or the like. In some embodiments, the developing process may be a dry process.

In an embodiment, the process 450 may continue with operation 455, which comprises transferring a pattern in the resist layer into the underlayer with an etching process. In an embodiment, the etching process may be a dry etching process. Since scum is limited or avoided, the pattern transfer is more effective and there is a smaller chance of forming electrical bridges and or missing contact defects.

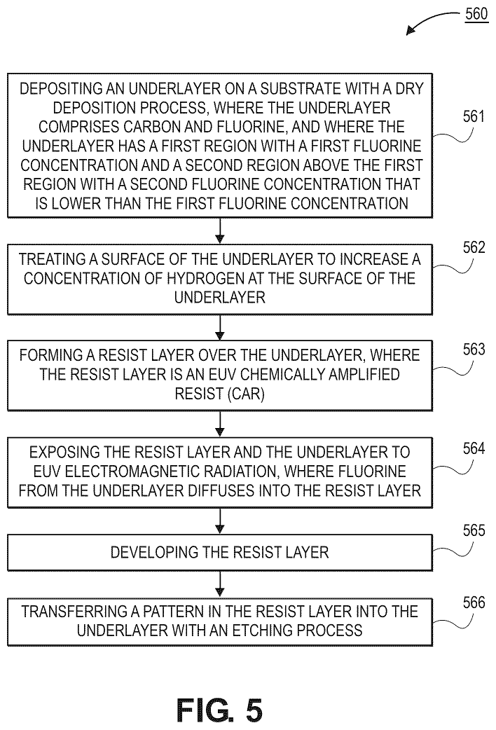

Referring now to FIG. 5, a flow diagram of a process 560 for patterning a patterning stack over a substrate with an underlayer that comprises fluorine is shown, in accordance with an embodiment. In an embodiment, the process 560 may begin with operation 561, which comprises depositing an underlayer on a substrate with a dry deposition process. In an embodiment, the underlayer comprises carbon and fluorine. The underlayer may have a first region with a first fluorine concentration and a second region above the first region with a second fluorine concentration that is lower than the first fluorine concentration. In an embodiment, the formation of the underlayer may be implemented with any combination of the deposition and/or doping processes described in greater detail herein.

In an embodiment, the process 560 may continue with operation 562, which comprises treating a surface of the underlayer to increase a concentration of hydrogen at the surface of the underlayer. The treatment may be a plasma treatment, a gas phase doping treatment, and/or the like.

In an embodiment, the process 560 may continue with operation 563, which comprises forming a resist layer over the underlayer. In an embodiment, the resist layer is an EUV CAR material. The resist layer may be deposited with a dry deposition process, a spin-coating process, or the like.

In an embodiment, the process 560 may continue with operation 564, which comprises exposing the resist layer and the underlayer to EUV electromagnetic radiation. In an embodiment, fluorine from the underlayer diffuses into the resist layer during and/or after the EUV exposure. In some embodiments, the underlayer may be heated in order to improve diffusion into the resist layer. In an embodiment, the diffusion of fluorine into the resist layer improves a deprotection reaction in the resist layer. Since the diffusion is activated by the EUV exposure, the fluorine diffuses into the resist layer from only regions of the underlayer that are exposed by the EUV electromagnetic radiation. As such the dose of EUV electromagnetic radiation can be reduced in order to improve throughput with minimal scum formation.

In an embodiment, the process 560 may continue with operation 565, which comprises developing the resist layer. The resist layer may be developed with a dissolving process, an etching process, or the like. In some embodiments, the developing process may be a dry process.

In an embodiment, the process 560 may continue with operation 566, which comprises transferring a pattern in the resist layer into the underlayer with an etching process. In an embodiment, the etching process may be a dry etching process. Since scum is limited or avoided, the pattern transfer is more effective and there is a smaller chance of forming electrical bridges and or missing contact defects.

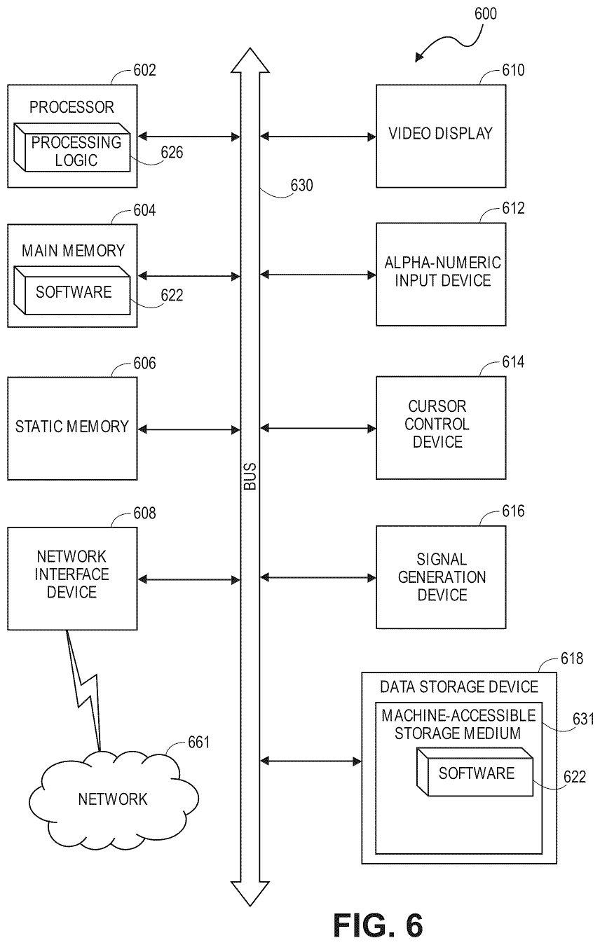

Referring now to FIG. 6, a block diagram of an exemplary computer system 600 of a processing tool is illustrated in accordance with an embodiment. In an embodiment, computer system 600 is coupled to and controls processing in the processing tool. Computer system 600 may be connected (e.g., networked) to other machines in a Local Area Network (LAN), an intranet, an extranet, or the Internet. Computer system 600 may operate in the capacity of a server or a client machine in a client-server network environment, or as a peer machine in a peer-to-peer (or distributed) network environment. Computer system 600 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 600, the term “machine” shall also be taken to include any collection of machines (e.g., computers) that individually or jointly execute a set (or multiple sets) of instructions to perform any one or more of the methodologies described herein.

Computer system 600 may include a computer program product, or software 622, having a non-transitory machine-readable medium having stored thereon instructions, which may be used to program computer system 600 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 600 includes a system processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

System processor 602 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 602 may also be one or more special-purpose processing devices such as an application specific integrated circuit (ASIC), a field programmable gate array (FPGA), a digital signal system processor (DSP), network system processor, or the like. System processor 602 is configured to execute the processing logic 626 for performing the operations described herein.

The computer system 600 may further include a system network interface device 608 for communicating with other devices or machines. The computer system 600 may also include a video display unit 610 (e.g., a liquid crystal display (LCD), a light emitting diode display (LED), or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium 631 (or more specifically a computer-readable storage medium) on which is stored one or more sets of instructions (e.g., software 622) embodying any one or more of the methodologies or functions described herein. The software 622 may also reside, completely or at least partially, within the main memory 604 and/or within the system processor 602 during execution thereof by the computer system 600, the main memory 604 and the system processor 602 also constituting machine-readable storage media. The software 622 may further be transmitted or received over a network 661 via the system network interface device 608. In an embodiment, the network interface device 608 may operate using RF coupling, optical coupling, acoustic coupling, or inductive coupling.

While the machine-accessible storage medium 631 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method, comprising:
forming an underlayer over a substrate, wherein the underlayer is an extreme ultraviolet (EUV) resist that comprises carbon and fluorine;
forming a resist layer over the underlayer, wherein the resist layer is an EUV chemically amplified resist (CAR);
exposing the resist layer and the underlayer to EUV electromagnetic radiation, wherein fluorine from the underlayer diffuses into the resist layer; and
developing the resist layer.

2. The method of claim 1, wherein the fluorine diffuses from only regions of the underlayer that are exposed by the EUV electromagnetic radiation.

3. The method of claim 1, wherein the underlayer is formed with a dry deposition process that comprises a carbon containing precursor and a fluorine containing precursor.

4. The method of claim 3, wherein the carbon containing precursor and the fluorine containing precursor are flown into a chamber simultaneously.

5. The method of claim 3, wherein the carbon containing precursor and the fluorine containing precursor are flown into a chamber sequentially in one or more cycles.

6. The method of claim 1, wherein the underlayer is formed with an atomic layer deposition (ALD) process, a chemical vapor deposition (CVD) process, a molecular layer deposition (MLD) process, or a spin-on process.

7. The method of claim 1, wherein the fluorine is integrated into the underlayer with an in-situ doping process, a plasma doping (PLAD) process, a beamline implant process, an ion implantation process, or a gas phase doping process.

8. The method of claim 1, further comprising:
treating a surface of the underlayer with a treatment that increases a concentration of hydrogen at a surface of the underlayer.

9. The method of claim 1, wherein a concentration of fluorine is non-uniform through a thickness of the underlayer.

10. The method of claim 9, wherein a first region of the underlayer has a first concentration of fluorine and a second region of the underlayer that includes a surface of the underlayer has a second concentration of fluorine that is lower than the first concentration of fluorine.

11. A patterning stack, comprising:
a substrate;
an underlayer over the substrate, wherein the underlayer comprises carbon and fluorine, and wherein the underlayer is an extreme ultraviolet (EUV) resist; and
a resist layer over the underlayer, wherein the resist layer is an EUV chemically amplified resist (CAR).

12. The patterning stack of claim 11, wherein the underlayer comprises a non-uniform fluorine concentration through a thickness of the underlayer.

13. The patterning stack of claim 11, wherein a surface of the underlayer has a first fluorine concentration that is lower than a second fluorine concentration of a bulk of the underlayer.

14. The patterning stack of claim 11, wherein a surface of the underlayer has a first hydrogen concentration that is higher than a hydrogen concentration of a bulk of the underlayer.

15. The patterning stack of claim 11, wherein fluorine from regions of the underlayer that are exposed to EUV electromagnetic radiation diffuses into the resist layer.

16. The patterning stack of claim 11, wherein the underlayer comprises alternating first sub-layers and second sub-layers, wherein the first sub-layers have a first fluorine concentration and the second sub-layers have a second fluorine concentration that is lower than the first fluorine concentration.

17. A method, comprising:
depositing an underlayer on a substrate with a dry deposition process, wherein the underlayer comprises carbon and fluorine, and wherein the underlayer has a first region with a first fluorine concentration and a second region above the first region with a second fluorine concentration that is lower than the first fluorine concentration;
treating a surface of the underlayer to increase a concentration of hydrogen at the surface of the underlayer;
forming a resist layer over the underlayer, wherein the resist layer is an EUV chemically amplified resist (CAR);
exposing the resist layer and the underlayer to EUV electromagnetic radiation, wherein fluorine from the underlayer diffuses into the resist layer; and
developing the resist layer.

18. The method of claim 17, wherein the underlayer is formed with an atomic layer deposition (ALD) process, a chemical vapor deposition (CVD) process, or a molecular layer deposition (MLD) process.

19. The method of claim 17, wherein the resist layer is formed with a spin-coating process.

20. The method of claim 17, wherein the second region comprises the surface of the underlayer, and wherein the second fluorine concentration is approximately 1% by weight or less.
